(19) United States
(12) Patent Application Publication
(10) Pub. No.: US 2008/0157300 A1
(43) Pub. Date: Jul. 3, 2008

(54) Thermally Enhanced IC Package and Method

(76) Inventors: Shih-Fang Chuang, McKinney, TX (US); Howard R. Test, Plano, TX (US)

Correspondence Address: TEXAS INSTRUMENTS INCORPORATED, P O BOX 655474, M/S 3999, DALLAS, TX, 75265, US

(21) Appl. No.: 11/672,765

(22) Filed: Feb. 8, 2007

Related U.S. Application Data
(60) Provisional application No. 60/871,992, filed on Dec. 27, 2006.

(51) Int. Cl. H01L 23/495; H01L 21/56

(52) U.S. Cl. 257/675; 438/118; 438/122; 257/E21.502; 257/E23.051

(57) ABSTRACT

Methods for assembling thermally enhanced semiconductor device packages are disclosed in which a chip assembly has a chip affixed to a leadframe. A thermal pad is affixed to a surface of the chip, and the chip assembly is encapsulated whereby a surface of the thermal pad remains exposed to form at least a portion of a surface of the package favorable for the egress of heat from the chip. Also disclosed are thermally enhanced semiconductor device packages made using the methods of the invention.

### PRIORITY ENTITLEMENT

This application claims priority based on Provisional Patent Application Ser. No. 60/871,992 filed on Dec. 27, 2006, which is incorporated herein for all purposes by this reference. This application and the Provisional Patent Application have at least one common inventor and are assigned to the same entity.

### TECHNICAL FIELD

The invention relates to electronic semiconductor devices and manufacturing. More particularly, the invention relates to designs for promoting heat egress from packaged semiconductor devices and to methods for the manufacture of the same.

### BACKGROUND OF THE INVENTION

In conventional semiconductor device packages, a semiconductor chip is mounted on a metallic leadframe with metallic connections and/or an adhesive material. Bond wires or contact pads on the chip are coupled with contact pads incorporated into the surface of the substrate. An encapsulant material forms a protective covering over the chip, bond wires, and some or all of the leadframe. Reductions in package size are constantly being pursued in the arts. With size reduction comes a high interconnection density, which can lead to a concentration of excess heat generated during operation of the circuitry. In general, the semiconductor chip in the packaged device generates heat when operated and cools when inactive. Due to the changes in temperature, the package as a whole tends to thermally expand and contract. However, in many cases the thermal expansion behavior of the package, its internal components, e.g., chip, leadframe, and underlying PCB, can differ, causing stresses to occur at the connecting joints, or within the layers of the package, or among the components of the IC chip itself.

The excess heat making its departure from an IC package common in the arts may be understood in terms of following three thermal paths. One potential thermal path is in the lateral, planar directions. Typically, the chip is isolated in all planar directions by surrounding mold compound, however, which generally has poor heat conduction properties, limiting this potential thermal path. In packages with multilayer substrates, heat can be spread out laterally somewhat as it travels toward the top or bottom layers, but these paths are necessarily limited by the area of the package, which in most cases is intentionally minimized.

The thermal paths through the “bottom” and “top” of the chip are therefore usually the most beneficial. Of course, a package may be inverted, and the top and bottom of the package are relative to its orientation. Herein, as is common in the art, the terms “bottom” and “top” refer to the substrate or PCB side of a package, and the opposite, molded side, respectively. The thermal path from the “bottom” of the chip, that is, through the substrate, is often the most direct. This path is sometimes improved by the addition of thermal vias or thermal solder balls designed to increase heat conduction through the chip and substrate and into the PCB beyond the package. To further address the problem of dissipating excess heat, packaged semiconductor devices are known in the arts which are characterized by a heat spreader interposed between the semiconductor chip and the PCB. The heat spreader is typically made from copper or other metal or from ceramic or other material selected for its heat conduction properties. This technology, however, has its own problems. One problem is related to assembly of the package on the PCB. Manufacturing and interposing the heat spreader between the semiconductor chip and the PCB complicates production procedures, resulting in increased costs. Also, there are various challenges to permanently attaching the heat spreader to the substrate, and in sealing the junctions between the heat spreader, chip, and substrate. Also, owing to the rigid attachment of the heat spreader to the PCB, there may be a degradation in reliability of the device due to the effects of thermally-induced stresses. Additionally, although it is desirable to make the heat spreader large in order to dissipate heat more effectively, larger sizes can lead to further problems such as increased susceptibility to warpage or decreased reliability under stress.

Heat may also travel from the chip through the “top” of the package. This is typically a relatively poor heat path due to inherent heat resistance of the encapsulant material covering the chip. It is known in the arts to attempt to improve this thermal path by the addition of an external heat sink to the outside of the package. Although sometimes helpful, this approach is necessarily limited by the inefficient heat transfer characteristics of the intervening mold compound. It is also known in the arts to use mold compound material having improved heat-conduction properties, but this approach is hampered by the shortcomings of such material, which, for example, may have a coefficient of thermal expansion dissimilar to that of other package components, can be relatively expensive, and is less effective at transferring heat than material such as metal.

In a flip-chip package, a chip is mounted on a substrate such as a PCB board or leadframe in a “flipped” or “face down” posture by means of conductive bumps, such as aluminum or copper bond pads on the surface of the chip. Electrical connections are achieved by connecting the conductive bumps provided on the surface of the chips with bond pads on the substrate. The flip-chip connection to the underlying substrate is generally formed using a reflow process. After the chip is attached, underfill is added between the chip and the substrate for strength and durability. Because flip-chips do not require wirebonds, their size is relatively small in comparison to their wirebonded counterparts. The metal connections between the chip surface and underlying substrate can provide a direct thermal path through the “bottom” of the package for the egress of heat produced during the operation of the chip. The potential for improved heat egress through the “top” of the mounted chip is limited in conventional packages however, which typically entirely engulf the chip in encapsulant, impeding heat transmission.

In addition to the problems identified above, thermal enhancements known in the arts for IC packages are faced with the additional problem of tending to increase the cost of the overall package. In general, to the extent the standard assembly process is disrupted, process efficiency and yields decrease, and costs increase. Due to these and other problems, it would be useful and advantageous to provide semiconductor packages, particularly relatively small packages such as for example QFN and other high-density flip-chip packages, with improved thermal conduction properties, and to provide manufacturing methods for the same.

### SUMMARY OF THE INVENTION

In carrying out the principles of the present invention, using methods compatible with established manufacturing processes, packaged microelectronic semiconductor devices are provided with improved thermal paths for promoting the egress of heat from the chip, and ultimately from the package. In general, in accordance with preferred embodiments, the egress of heat from the chip to the outside the package is facilitated by refraining from blocking advantageous thermal paths with mold compound, and further by enhancing thermal paths.

According to one aspect of the invention, a method for assembling a semiconductor device package includes a step of providing a flip-chip assembly. The flip-chip assembly has a leadframe with a chip attached. A thermal pad is affixed to the exposed surface of the chip. The assembly is encapsulated in order to encase the chip while leaving the surface of the thermal pad exposed at the outer surface of the package.

According to other aspects of the invention, method steps are included in alternative preferred embodiments whereby a thermal pad is affixed to the chip using die attach film or curable die attach adhesive.

According to another aspect of the invention, in a preferred embodiment, a method for assembling a semiconductor device package includes steps of applying die attach film to the surface of a thermal pad and placing the prepared thermal pad into a mold. In a further step, the thermal pad is affixed to a surface of a chip by placing the flip-chip assembly into the mold to make contact with the die attach film.

According to yet another aspect of the invention, a flip-chip assembly is encapsulated prior to affixing an external thermal pad to an exposed surface of the chip.

According to another aspect of the invention, a flip-chip assembly includes a leadframe having a chip affixed to the leadframe. The chip is provided with an integrated thermal pad, the surface of which remains exposed in the final package.

According to still another aspect of the invention, a flip-chip assembly includes a leadframe having a chip affixed to the leadframe. The chip is provided with an integrated thermal pad. An external thermal pad is affixed to the surface of the chip, the external thermal pad remaining exposed in the final package.

The invention has advantages including but not limited to providing methods and devices offering improvements in facilitating heat egress from semiconductor device packages. This and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a simplified process flow diagram illustrating steps in preferred methods of the invention;

FIG. 2 is a cutaway side view of an example of a preferred embodiment of a thermally enhanced IC package according to the invention;

FIG. 3 is a cutaway side view of another example of a preferred embodiment of a thermally enhanced IC package according to the invention;

FIG. 4 is a top view of the embodiments of the invention shown in the examples of FIGS. 2 and 3;

FIG. 5 is a top view of alternative embodiments of the invention shown in the examples of FIGS. 2 and 3;

FIG. 6 is a cutaway side view of an example of another implementation of an embodiment of a thermally enhanced IC package according to the invention;

FIG. 7 is a cutaway side view of another exemplary embodiment of a thermally enhanced IC package according to the invention;

FIG. 8 is a cutaway side view of yet another example of a preferred embodiment of a thermally enhanced IC package according to the invention;

FIG. 9 is a top view of alternative embodiments of the invention shown in the examples of FIGS. 6 through 8, and FIG. 13;

FIG. 10 is another top view showing alternative embodiments of the invention shown in the examples of FIGS. 6 through 8 and FIG. 13;

FIG. 11 is a cutaway side view of an example of a preferred embodiment of a thermally enhanced IC package according to the invention;

FIG. 12 is a top view of the embodiment of the invention shown in the example of FIG. 11;

FIG. 13 is a cutaway side view of an example of an alternative embodiment of a thermally enhanced IC package according to the invention; and

FIG. 14 is a simplified process flow diagram illustrating steps in alternative embodiments of methods of the invention.

References in the detailed description correspond to like references in the various drawings unless otherwise noted. Descriptive and directional terms used in the written description such as first, second, top, bottom, upper, lower, side, and so forth, refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

In general, the invention provides thermally enhanced IC package assemblies with improved paths for the egress of heat produced in the IC. As shown and described herein, preferred embodiments of the invention produce one or more useful advantages.

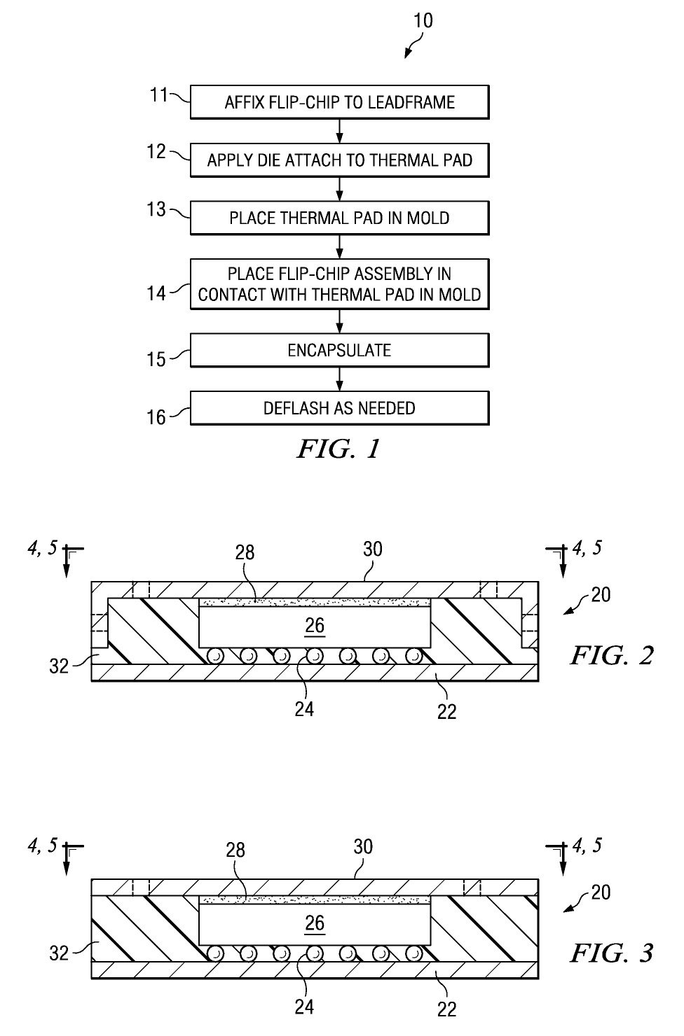

Now referring primarily to FIG. 1, an overview of a preferred embodiment of the invention is shown in a simplified process flow diagram. A method for assembling a thermally enhanced semiconductor device package 10 includes a step of affixing a chip to a leadframe 11. Preferably, the chip is a flip-chip attached to the leadframe using metal bumps and/or solder reflowed to complete electrical connections between the leadframe and chip as known in the arts. Typically, the remaining space between the chip and leadframe is also filled with dielectric underfill material such as epoxy. As shown at step 12, die attach material is applied to a thermal pad configured for placement on the chip. Typically, the thermal pad is equal to or greater than the chip in area. Die attach film or curable die attach adhesive may be used. Preferably, the thermal pad is metal, alloy, or semiconductor material selected for its heat transmitting properties. The thermal pad, with die attach material, is preferably placed within a mold cavity 13 prior to placement of the assembled flip-chip and leadframe 14 in contact with the die attach material on the thermal pad within the mold. Subsequently, mold compound is introduced into the mold cavity and is cured to encapsulate the flip-chip and leadframe 15. Mold flash is preferably removed 16 as required to complete the package. Film may be used to line the mold cavity to prevent or minimize mold compound bleeding and thereby minimize the need for deflashing. Preferably, the coefficients of thermal expansion (CTE) and other physical properties among the chip, leadframe, underfill, thermal pad, die attach material, and mold compound are selected in order to facilitate heat transmission and to ensure durability when subjected to thermal cycling. In preferred embodiments of the invention, the surface of the thermal pad remains exposed at the outer surface of the completed package in order to facilitate heat transfer.

A cutaway side view of an example of a preferred embodiment of a thermally enhanced semiconductor device package 20 is shown in FIG. 2. A substrate 22, for example a metal leadframe or multi-layer substrate having numerous semiconductor and metal layers, is preferably prepared to accept a chip 26. The chip 26, preferably a flip-chip, is operably coupled to the substrate 22 with metal bumps or solder balls 24, which are reflowed to form secure electrical connections among corresponding contact points. Die attach material 28, such as die attach film or curable die attach adhesive, is used to connect a thermal pad 30 to the surface of the chip 26. In preferred implementations of methods of the invention, the die attach material 28 is first applied to the thermal pad 30, which is then placed into a mold cavity where it is ultimately brought into contact with the surface of the chip 26. Using pre-applied die attach film is preferred, as it helps provide tight mold fit, minimizing the potential for bleeding in subsequent encapsulating steps, and perhaps reducing the need for deflashing. An alternative method is to apply the die attach material 28 directly to the chip 26 prior to bringing the thermal pad 30 to bear on the surface of the chip 26. Subsequently, the exposed portions of the chip 26, substrate 22, and thermal pad 30 are encapsulated with mold compound 32 familiar in the art such as curable plastic or epoxy resin. The package 20 provides a direct thermal path from the chip 26 through the thermal pad 30, facilitating the rapid egress of heat from the chip 26 to the outside of the package 20.

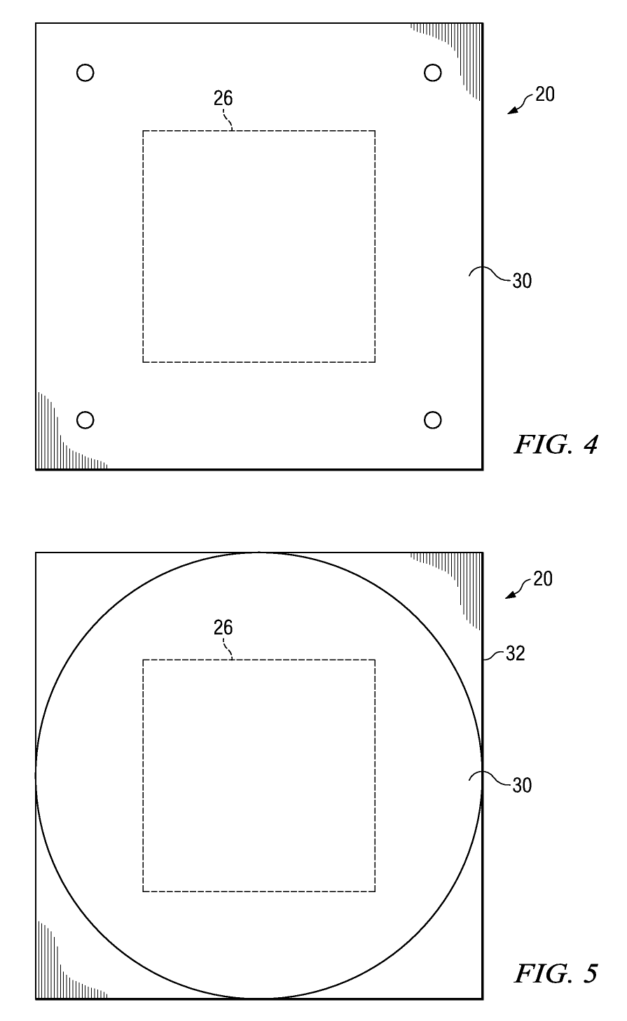

The possible variations within the scope of the invention are numerous and cannot all be shown. Another example of a preferred embodiment of a package system of the invention 20 is depicted in the cutaway side view of FIG. 3. This alternative embodiment of the invention is similar in construction to that shown in FIG. 2. A substrate 22 has a chip 26 affixed thereto with metal bumps or solder balls 24. Die attach material 28 connects a thermal pad 30 to the surface of the chip 26. Mold compound 32 encapsulates the exposed portions of the chip 26, substrate 22, and thermal pad 30 to complete the body of the package 20. A direct thermal path is provided from the chip 26 through the thermal pad 30 facilitating heat egress. The thermal pad 30 shown in FIG. 3 differs in shape from that of FIG. 2, demonstrating one potential variation in the configuration of the invention. Further illustrating the possibility for varying implementations of the invention, FIGS. 4 and 5 are top views showing two of the alternative shapes of thermal pads that may be used in implementing the embodiments shown in FIGS. 2 and 3. The surface of the thermal pad 30 is shown, providing a relatively large area at the outside of the package 20 for transmitting heat generated by the chip 26 attached to the opposing side of the pad 30.

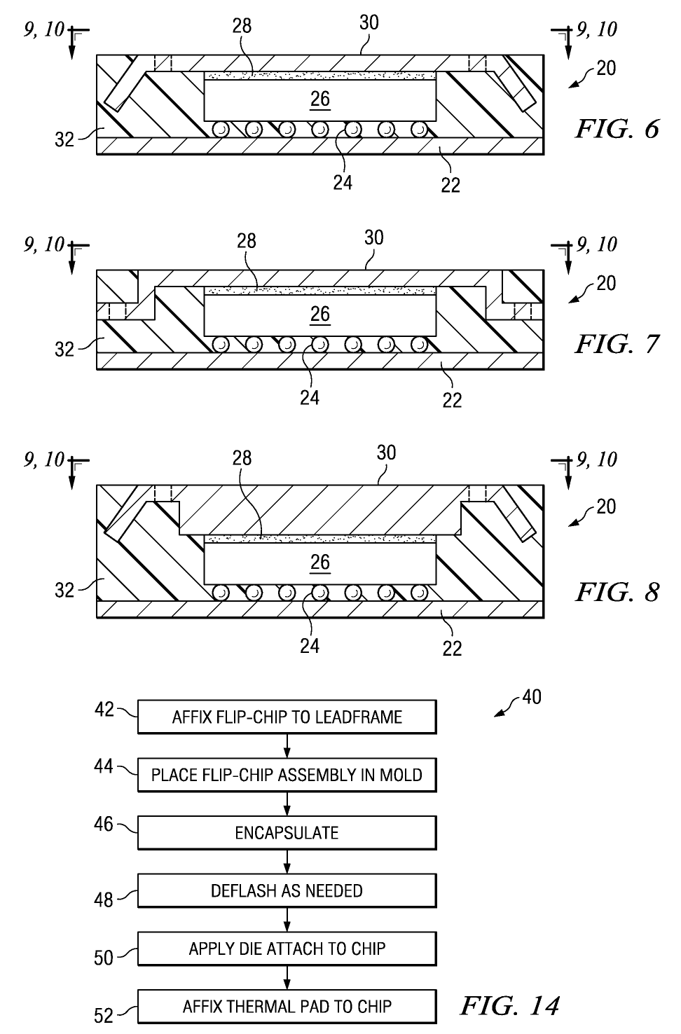

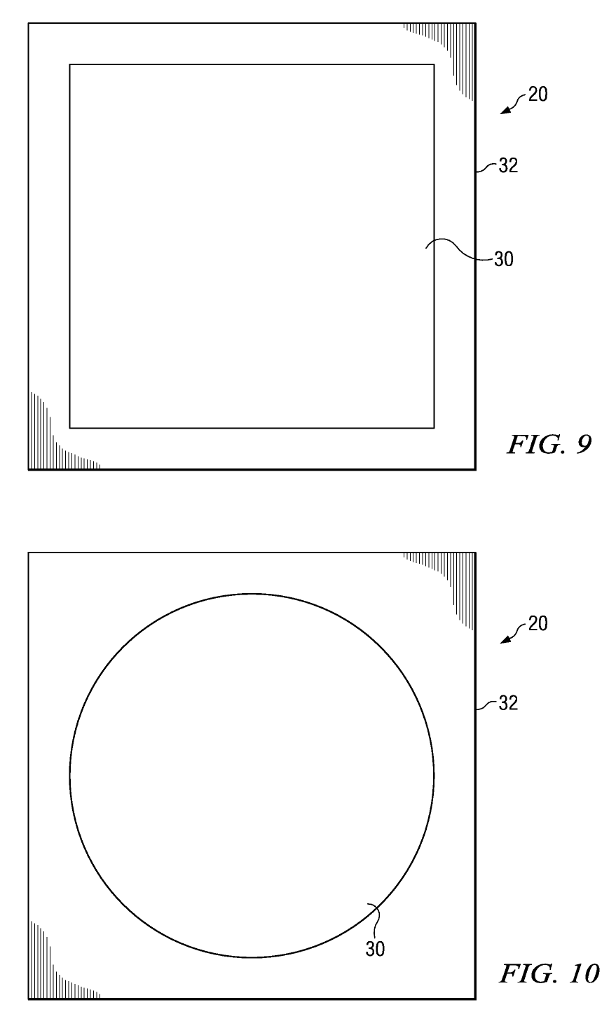

Additional examples of preferred embodiments of thermally enhanced packages 20 of the invention are depicted in the cutaway side views of FIGS. 6 through 8. As shown, the thermal pad 30 may take different forms depending upon the requirements of the manufacturing process and desired heat transfer characteristics. The aspect ratio, shape, and profile of the thermal pad 30 may be varied without departure from the principles of the invention. In addition to the potential for using differing profiles as shown in FIGS. 6 and 7, it should be appreciated that the thickness of the thermal pad 30 may also be varied, as illustrated in FIG. 8. FIGS. 9 and 10 show top views, illustrating the thermal pad 30 exposed at the surface of the package 20. Each of the top views of FIGS. 9 and 10 is equally applicable to each of the embodiments shown in the side views of FIGS. 6 through 8.

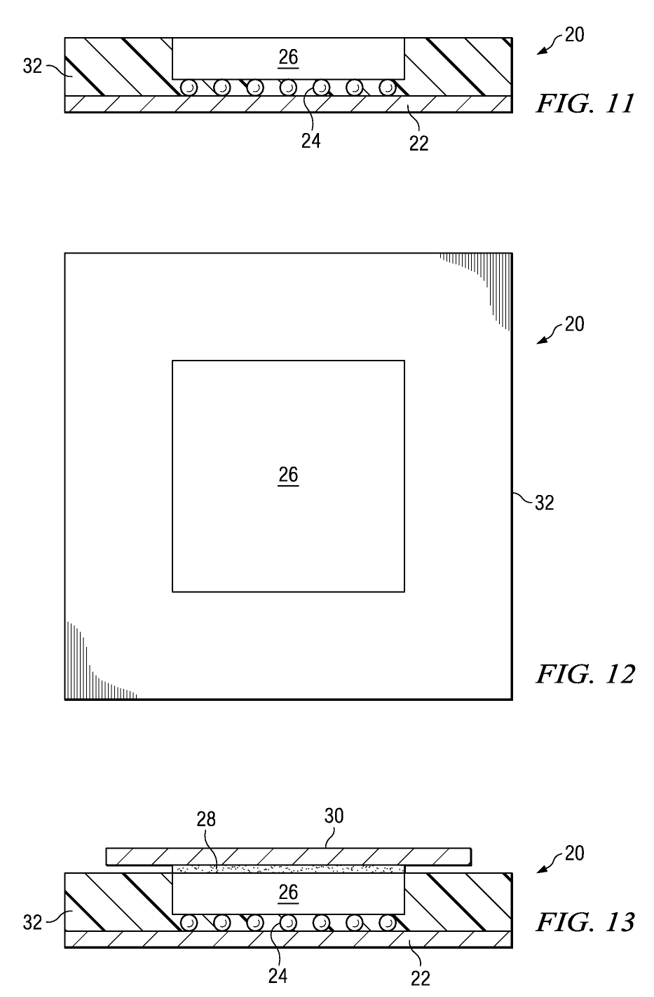

A further example of an alternative embodiment of the invention is depicted in FIG. 11. In this particular embodiment, a direct thermal path from the chip 26 to the outside of the package 20 is provided without the use of a thermal pad external to the chip itself 26. Preferably, the chip 26 is affixed to a leadframe 22 in the manner described and shown elsewhere herein. Mold compound 32 encapsulates the exposed portions of the chip 26 and leadframe 22, and an exposed surface of the chip 26 completes the body of the package 20. A direct thermal path is provided through the exposed surface of the chip 26 facilitating heat egress. A corresponding top view is shown in FIG. 12. In this alternative embodiment of the invention, a chip 26 with increased thickness may be used. The increased thickness of the chip 26 preferably is achieved by using an outer layer of increased thickness in a multi-layer chip. In effect, a thermal pad is thus integrated into the chip 26, either through the addition of metal, or through the use of thickened semiconductor material. Preferably, the integrated thermal pad used in the preferred embodiments of the invention represented by FIG. 11 is made using silicon of increased thickness. For example, in a typical QFN (quad flat no-lead) package application, silicon of approximately 23.4 to 24 mils in thickness may be used. The exposed surface of the chip 26 may be deflashed or ground subsequent to encapsulation in order enhance the exposed surface for heat egress. Another variation is illustrated in FIG. 13 in which, subsequent to molding, an external thermal pad 30 is affixed to the outer surface of a chip 26 in the underlying configuration shown in FIG. 11 and 12. The external thermal pad 30 is preferably affixed to the surface of the chip 26 using die attach film 28 or curable die attach adhesive. The external thermal pad 30 may be used in alternative embodiments of the invention either with or without an integrated thermal pad. It should be appreciated by those skilled in the arts that various shapes, sizes, and aspect ratios are acceptable for this embodiment, a few examples of which are shown in the top views of FIGS. 9 and 10.

The alternative embodiments of the invention depicted in FIGS. 11 through 13 and described with reference thereto are further illustrated in FIG. 14. A process flow diagram 40 is shown in which a flip-chip assembly is constructed 42, preferably with a chip affixed to a leadframe using metal bumps or solder. The chip in this alternative embodiment preferably includes an integrated thermal pad for facilitating the egress of heat through the surface of the chip. The integrated thermal pad is preferably incorporated into the layers of the multi-layer chip during its manufacture by including a thick outer layer of metallic or semiconductor material. The flip-chip and leadframe assembly is placed in a mold cavity 44 in preparation for encapsulation. The assembly is preferably encapsulated 46 such that the surface of the chip remains exposed to form the outside of the package. The package may then be deflashed to remove excess mold compound as necessary 48. In some cases, it may be preferable to lightly grind the surface of the chip to improve the continuity of the exposed surface. Thus, a preferred embodiment of the invention may be implemented using steps 42 through 48 only, providing a package having a chip with an integrated thermal pad exposed at the surface. Continuing with step 50, another alternative embodiment of the invention is shown with the addition of die attach material to the exposed surface of the chip. Die attach tape or curable die attach adhesive may be used. A thermal pad may then be affixed externally to the surface of the chip 52, providing a further enhanced thermal path for the egress of heat from the internal thermal pad of the underlying chip. As indicated in reference to other preferred embodiments of the invention, in order to reduce or eliminate the need for deflashing, additional steps may be included for placing film on one or more surfaces of the mold prior to placing the assembly into the mold and introducing mold compound to encapsulate the flip-chip assembly.

The invention provides advantages including but not limited to improved heat egress from microelectronic semiconductor device packages, increased package reliability, and reduced costs. While the invention has been described with reference to certain illustrative embodiments, the methods and systems described are not intended to be construed in a limiting sense. Various modifications and combinations of the illustrative embodiments as well as other advantages and embodiments of the invention will be apparent to persons skilled in the art upon reference to the description and claims.

We claim:

1. A method for assembling a semiconductor device package comprising:
providing a flip-chip assembly further comprising a leadframe having a chip affixed to the leadframe;
affixing a thermal pad to a surface of the chip; and
encapsulating the flip-chip assembly, whereby a surface of the thermal pad remains exposed to form at least a portion of a surface of the package.

2. A method according to claim 1 further comprising a step whereby a surface of the thermal pad is affixed to an adjoining surface of the chip using die attach film.

3. A method according to claim 1 further comprising a step whereby a surface of the thermal pad is affixed to a surface of the chip using curable die attach adhesive.

4. A method according to claim 1 further comprising the steps of;
applying die attach material to a surface of the thermal pad;
placing the thermal pad having applied die attach material into a mold; and
wherein the step of affixing the thermal pad to a surface of the chip further comprises placing the flip-chip assembly into the mold such that a surface of the chip becomes affixed to the die attach material applied to the thermal pad.

5. A method according to claim 1 further comprising the step of deflashing the package subsequent to the encapsulation step.

6. A method for assembling a semiconductor device package comprising:
providing a flip-chip assembly further comprising a leadframe having a chip affixed to the leadframe, the chip having an integrated thermal pad; and
encapsulating the flip-chip assembly, whereby a surface of the chip remains exposed to form at least a portion of a surface of the package.

7. A method according to claim 6 further comprising the step of grinding the exposed surface of the chip subsequent to the encapsulating step.

8. A method according to claim 6 further comprising the step of affixing a thermal pad to the exposed surface of the chip subsequent to the encapsulating step whereby a surface of the thermal pad remains exposed to form at least a portion of a surface of the package.

9. A method according to claim 6 wherein the step of encapsulating the flip-chip assembly further comprises placing film on one or more surfaces of a mold, subsequently placing the assembly into the mold, and introducing curable mold compound into the mold for encapsulating the flip-chip assembly.

10. A semiconductor device package comprising:
a flip-chip assembly further comprising a leadframe having a chip, the chip having a bottom surface affixed to a top surface of the leadframe; and
encapsulant encapsulating the flip-chip assembly, wherein a bottom surface of the leadframe and a top surface of the chip remain exposed.

11. A package according to claim 10 further comprising a thermal pad affixed to a top surface of the chip, wherein a top surface of the thermal pad remains exposed.

12. A package according to claim 10 further comprising a thermal pad integrated into the chip, wherein the integrated thermal pad comprises a thick outer layer of a multi-layer chip.

13. A package according to claim 10 further comprising a thermal pad integrated into the chip, wherein the integrated thermal pad comprises a thick outer metallic layer of a multi-layer chip.

14. A package according to claim 10 further comprising film die attach securing the bottom surface of the thermal pad to the top surface of the chip.

15. A package according to claim 10 further comprising cured dispensed die attach adhesive securing the bottom surface of the thermal pad to the top surface of the chip.

16. A package according to claim 10 further comprising a QFN package.

17. A package according to claim 10 wherein the chip further comprises a chip having a thickness of more than about 23 mils.

18. A package according to claim 10 wherein the chip further comprises a chip having a thickness within a range of about 23 mils to about 24 mils.
